(19) United States
(12) Patent Application Publication
(10) Pub. No.: US 2007/0251454 A1
(43) Pub. Date: Nov. 1, 2007

(54) Plasma Surface Processing System and Supply Device for Plasma Processing Solution Therefor

(75) Inventors: Young-Man Jeong, Gyeongsangnam-do (KR); Jung-Geun Oh, Gyeongsangnam-do (KR)

Correspondence Address: BIRCH STEWART KOLASCH & BIRCH, PO BOX 747, FALLS CHURCH, VA, 22040-0747, US

(73) Assignee: LG Electronics Inc., Seoul (KR)

(21) Appl. No.: 10/565,107

(22) PCT Filed: Jul. 22, 2003
(86) PCT No.: PCT/KR03/01451

§ 371 Date: Mar. 5, 2007

(51) Int. Cl. C23C 16/44

(52) U.S. Cl. 118/723 R

(57) ABSTRACT

Disclosed is a plasma surface processing system for processing a surface of an object to be processed (110) by forming plasma in a reaction chamber (100), the system including a supply device (230) for plasma processing solution (201) which supplies a processing material which forms plasma in a chamber (100) into the reaction chamber as a liquid drop form.

### TECHNICAL FIELD

The present invention relates to a plasma surface processing system, and more particularly, to a plasma surface processing system for plasma surface processing on a surface of an object to be processed.

### BACKGROUND ART

In general, as shown in PCT publication gazette WO 9927156 A and WO 9928530 A, a plasma surface processing system is a system for processing a surface of a metal material, an object to be processed, in order to apply various characteristics such as corrosion resistance, hydrophobicity, or hyrrophile by forming plasma with reaction gas by applying a power source to an electrode installed in a hermetic reaction chamber.

Especially, in the plasma surface processing system, reaction gas is injected into the reaction chamber in order to realize a required characteristic of the object to be processed. That is, by a processing material injected into the reaction chamber, a characteristic of a polymerization film formed on a surface of the object to be processed becomes different.

Accordingly, the plasma surface processing system requires a supply device for properly injecting a processing material which forms plasma into the reaction chamber.

### DISCLOSURE OF THE INVENTION

Therefore, it is an object of the present invention to provide a plasma surface processing system including a supply device for plasma processing solution which supplies a processing material which forms plasma into a reaction chamber as a liquid drop form.

To achieve these objects, there is provided a plasma surface processing system for processing a surface of an object to be processed by forming plasma in a reaction chamber, the system including a supply device for plasma processing solution which supplies a processing material which forms plasma in a reaction chamber into the reaction chamber as a liquid drop form.

To achieve these objects, there is also provided a supply device for plasma processing solution which supplies a processing material which forms plasma into a reaction chamber as a liquid drop form in a plasma surface processing system for processing a surface of an object to be processed by forming plasma in a reaction chamber,

### BRIEF DESCRIPTION OF THE DRAWINGS

FIG. 1 is a construction view of a plasma surface processing system according to the present invention; and

FIG. 2 is a construction view showing a reservoir and a processing solution supplementary device of the plasma surface processing system of FIG. 1.

### MODES FOR CARRYING OUT THE PREFERRED EMBODIMENTS

Hereinafter, a plasma surface processing system according to the present invention will be explained with reference to the attaching drawings.

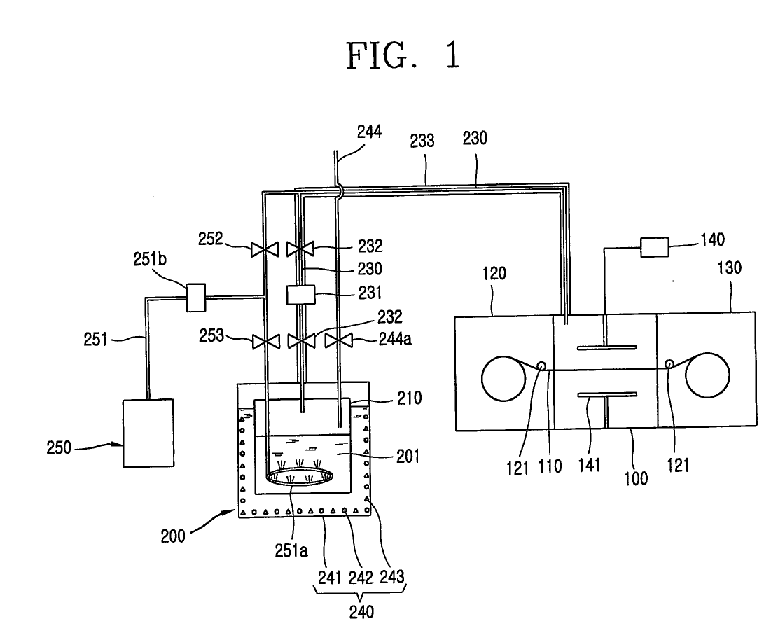

As shown in FIG. 1, the plasma surface processing system according to the present invention for processing a surface of an object to be processed 110 such as a metal material by forming plasma in a reaction chamber 100 includes a supply device for plasma processing solution 200 which supplies a processing material which forms plasma into the reaction chamber 100 as a liquid drop.

The plasma surface processing system according to the present invention, as disclosed in PCT publication gazette WO 9927156 A and WO 9928530 A, is a system for forming a polymerization film having a specific characteristic on a surface of the object to be processed 110 by using plasma.

The reaction chamber 100 is maintained in a hermetic state closed to a vacuum state under a predetermined pressure, and as shown in FIG. 1, is provided with an electrode 141 which applies a power source supplied from a power supply device 140 in order to form plasma.

Also, transfer chambers 120 and 130, or other chambers for consecutively transferring the object to be processed 110 or for another processing are installed adjacently to the reaction chamber 100 in order to consecutively process the surface of the object to be processed 110.

The object to be processed 100 is metal material such as aluminum sheet which is material of a fin constituting a part of a heat exchanger or an insulating material. Especially, in case that the object to be processed is metal material, the object to be processed can be one of electrodes.

As shown in FIG. 1, the supply device for plasma processing solution 200 includes: a processing solution reservoir 210 for storing plasma processing solution 201 as a hermetic state; a gas inflow pipe 251 connected to the reservoir 210 and for introducing carrier gas which carries liquid drops of the plasma processing solution; and a supply pipe 230 installed by connecting the reservoir 210 and the reaction chamber 100 in order to supply the carrier gas including liquid drops of the plasma processing solution into the reaction chamber 100.

The sort, amount, ratio of ingredients of processing solution is determined by a characteristic of a polymerization film to be formed on the surface of the object to be processed 110. For example, the processing solution may include hexamethyldisilazeane (HDMS), hexamethyidisiloxane (HDMSO), and etc.

The carrier gas inflow pipe 251 is installed in a state of being soaked in the processing solution 201 stored in the reservoir 210, and has a plurality of discharge holes 251a for forming processing solution foam by the carrier gas discharged from the inflow pipe 251.

Especially, an end portion of the carrier gas inflow pipe 251 preferably has a ring shape where the plurality of discharge holes 251a are formed in order to form foam more smoothly by carrier gas.

The carrier gas inflow pipe 251 is connected to a carrier gas storage tank where carrier gas is stored, and N₂ or He is used as the carrier gas.

A gas amount controller 251b for controlling amount of carrier gas is installed at the carrier gas inflow pipe 251.

The carrier gas inflow pipe 251 may be further provided with a separation pipe 251c connected to the reaction chamber 100 in order to introduce the carrier gas into the reaction chamber 100. At this time, gas flow control valves 252 and 253 are respectively installed at the separation pipe 251c and between a connection spot of the inflow pipe 251 and the separation pipe 251c and the reservoir 210.

The supply pipe 230 is further provided with a gas amount controller 231 for controlling amount of carrier gas including liquid drops of the processing solution.

Also, a pair of valves 232 for controlling flow of the carrier gas are installed at the supply pipe 230 up and down on the basis of the gas amount controller 231.

The supply pipe 230 can be separately installed by being prolonged from the reservoir 210 to the reaction chamber 100. However, as shown in FIG. 1, the supply pipe 230 is put together with the separation pipe 252 thus to be connected to the reaction chamber 100 in order to reduce construction components.

In the meantime, while carrier gas including the processing solution of a liquid state is injected into the reaction chamber 100, a pressure of the carrier gas is lowered. Temperature of the carrier gas is lowered in accordance with that the processing solution is evaporated. While the temperature of the carrier gas is lowered, an evaporation amount of the processing solution is decreased and thus supplying the processing solution of a proper amount into the reaction chamber 100 is impossible. Also, formation of the polymerization film at the surface of the object to be processed 110 is influenced.

Therefore, the plasma surface processing system according to the present invention provides a device for maintaining temperature of the carrier gas including the processing solution injected into the reaction chamber 100 constantly and controlling amount of supplied processing solution.

That is, the supply pipe 230 is further provided with a heater 233 for increasing temperature of the carrier gas including liquid drops of the processing solution.

Also, the reservoir 210 is further provided with a temperature control device 240 for controlling temperature of stored processing solution. The temperature control device 240 includes: a receiving tank 241 for receiving the reservoir 210 and in which insulating oil is filled; a heater 242 installed in the receiving tank 241 and for generating heat; and a cooling device 243 installed in the receiving tank 241 and for absorbing heat.

A pressure control pipe 244 for controlling pressure inside the reservoir 210 and discharging the carrier gas is installed at the reservoir 210, and a valve 244a for opening and closing the pressure control pipe 244 is installed at the pressure control pipe 244.

Meanwhile, new processing solution has to be supplemented into the reservoir 210 after processing solution is used. To this end, the reservoir 210 has to be opened and closed, which causes inconvenience. Therefore, in the present invention, a processing solution supplementary device 500 for supplementing plasma processing solution into the reservoir 210 is provided at the reservoir 210.

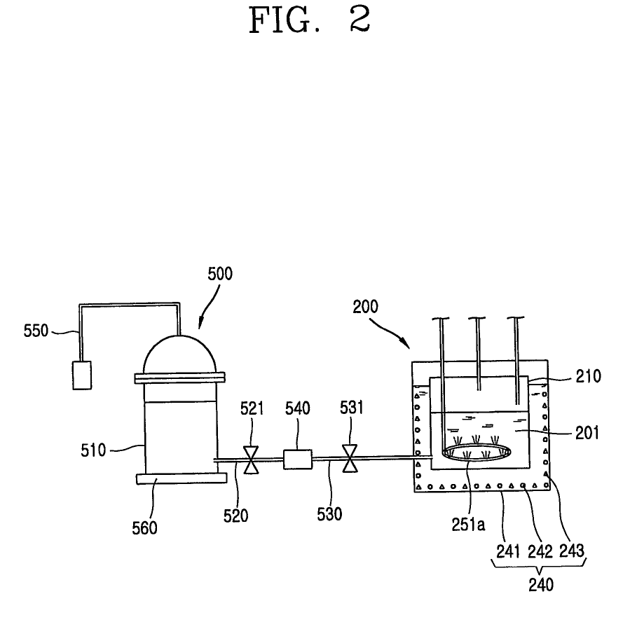

That is, as shown in FIG. 2, the processing solution supplementary device 500 includes: a first supplementary pipe 520 connected to the reservoir 210; a storage container 510 in which processing solution is stored; a second supplementary pipe 530 connected to the storage container 510; a connecting unit 540 for connecting the first supplementary pipe 520 and the second supplementary pipe 530; and valves 521 and 531 respectively installed at the first and second supplementary pipes 520 and 530.

A pressure apply device 550 for supplementing processing solution by pressurizing the processing solution is connected to an upper side of the storage container 510, and a mass measure device 560 for measuring amount of the processing solution is installed at a bottom of the storage container 510.

Operations of the plasma surface processing system according to the present invention will be explained in detail.

First, a power source is applied to the electrode 141 connected to the power supply device 140 by a controller (not shown), and at the same time, the object to be processed 110 is consecutively transferred by a transferring device (not shown).

Also, carrier gas including processing solution of a liquid state is injected into the reaction chamber 100 by the supply device for processing solution 200, plasma is formed by electric energy applied to the electrode 141, and a polymerization film having a specific characteristic is formed on the surface of the object to be processed 110.

Herein, supply processes of the processing solution will be explained in more detail. First, the carrier gas is introduced into the reservoir 210 through the inflow pipe 251, and thereby foam is formed and the carrier gas including the processing solution of a liquid state is supplied into the reaction chamber 100 through the supply pipe 230.

At this time, by evaporation of the processing solution and pressure lowering, temperature of the carrier gas is lowered. However, the temperature of the carrier gas can be constantly maintained by the heater 233 installed around the supply pipe 230.

Also, temperature inside the reservoir 210 is controlled by the temperature control device 240, and pressure inside the reservoir 210 is also controlled by the pressure control pipe 244.

Besides, in case that the processing solution is not sufficient in the reservoir 210, new processing solution is supplemented by the processing solution supplementary device 500.

The plasma surface processing system according to the present invention can perform a surface processing variously by providing the supply device for pressing solution which supplies a processing material which forms plasma in order to form a polymerization film having a specific characteristic on the surface of the object to be processed.

The plasma surface processing system according to the present invention can form the polymerization film of good quality on the surface of the object to be processed by constantly maintaining temperature and pressure of the supplied processing solution.

It will be apparent to those skilled in the art that various modifications and variations can be made in the present invention without departing from the spirit or scope of the invention. Thus, it is intended that the present invention cover modifications and variations of this invention provided they come within the scope of the appended claims and their equivalents.

1. A plasma surface processing system for processing a surface of a metal material by forming plasma in a reaction chamber, the system comprising a supply device for plasma processing solution which supplies a processing material which forms plasma into the reaction chamber as a liquid drop form in order to process the surface of the metal material.

2. The system of claim 1, wherein the supply device for plasma processing solution comprises: a processing solution reservoir for storing plasma processing solution 201 as a hermetic state; a carrier gas inflow pipe connected to the reservoir and for introducing carrier gas which carries liquid drops of the plasma processing solution; and a supply pipe installed by connecting the reservoir and the reaction chamber in order to supply the carrier gas including liquid drops of the plasma processing solution into the reaction chamber.

3. The system of claim 2, wherein the carrier gas inflow pipe is installed under a state of being soaked in the processing solution stored in the reservoir, and has a plurality of discharge holes for forming processing solution foam by the carrier gas discharged from the inflow pipe.

4. The system of claim 3, wherein an end portion of the carrier gas inflow pipe has a ring shape where the plurality of discharge holes are formed.

5. The system of claim 3, wherein the carrier gas inflow pipe is provided with a gas amount controller for controlling amount of carrier gas.

6. The system of claim 2, wherein the carrier gas inflow pipe is provided with a gas amount controller for controlling amount of carrier gas.

7. The system of claim 3, wherein the carrier gas inflow pipe is further provided with a separation pipe connected to the reaction chamber in order to introduce the carrier gas into the reaction chamber.

8. The system of claim 7, wherein gas flow control valves are respectively installed at the separation pipe and between a connection spot of the inflow pipe and the separation pipe and the reservoir.

9. The system of claim 7, wherein the separation pipe is connected to the supply pipe.

10. The system of claim 2, wherein the carrier gas inflow pipe is further provided with a separation pipe connected to the reaction chamber in order to introduce the carrier gas into the reaction chamber.

11. The system of claim 2, wherein the supply pipe is further provided with a gas amount controller for controlling amount of the carrier gas including liquid drops of the processing solution.

12. The system of claim 11, wherein a pair of valves for controlling flow of the carrier gas are installed at the supply pipe up and down on the basis of the gas amount controller.

13. The system of claim 2, wherein the reservoir is further provided with a temperature control device for controlling temperature of stored processing solution.

14. The system of claim 13, wherein the temperature control device comprises: a receiving tank for receiving the reservoir and in which insulating oil is filled; a heater installed in the receiving tank and for generating heat; and a cooling device installed in the receiving tank and for absorbing heat.

15. The system of claim 2, wherein the supply pipe is further provided with a heater for increasing temperature of the carrier gas including liquid drops of the processing solution.

16. The system of claim 1, wherein the surface of the metal material is consecutively processed.

17. The system of claim 1, wherein the metal material is an electrode.

18. The system of claim 1, wherein the processing solution is hexamethyldisilazeane (HDMS) or hexamethyldisiloxane (HDMSO).

19. The system of claim 1, wherein the carrier gas is N2 or He.

20. The system of claim 1, wherein the reservoir further comprises a processing solution supplementary device for supplementing plasma processing solution thereinto.

21. The system of claim 20, wherein the processing solution supplementary device comprises: a first supplementary pipe connected to the reservoir; a storage container in which processing solution is stored; a second supplementary pipe connected to the storage container; a connecting unit for connecting the first supplementary pipe and the second supplementary pipe; and valves respectively installed at the first and second supplementary pipes.

22. In a plasma surface processing system for processing a surface of a metal material by forming plasma in a reaction chamber, a supply device for plasma processing solution which supplies a processing material which forms plasma into the reaction chamber as a liquid drop form in order to process the surface of the metal material.
